(19) United States
(12) Patent Application Publication
(10) Pub. No.: US 2013/0256121 A1
(43) Pub. Date: Oct. 3, 2013

(54) Manufacturing method of reflective layer for reflective type liquid crystal

(71) Applicant: Jun Wang, Shenzhen (CN)

(72) Inventor: Jun Wang, Shenzhen (CN)

(73) Assignee: Shenzhen China Star Optoelcetronics Technology Co., Ltd., Shenzhen, Guangdong (CN)

(21) Appl. No.: 13/518,859

(22) PCT Filed: Apr. 11, 2012
(86) PCT No.: PCT/CN2012/073818

§ 371 Date: Jun. 22, 2012

(30) Foreign Application Priority Data
Mar. 31, 2012 (CN) 201210092845.9

(51) Int. Cl. C23C 14/35

(52) U.S. Cl. 204/192.27

(57) ABSTRACT

The present invention provides a manufacturing method of a reflective layer for a reflective type liquid crystal display, comprising: providing a manufacturing method of the reflective layer for a reflective type liquid crystal display, comprising: providing a substrate, the substrate comprising a reflective area and a non-reflective area; coating a photoresist to cover the non-reflective area; placing the substrate in a sputtering chamber for depositing a reflective metal layer on the reflective area of the substrate; passing the reaction gas into the sputtering chamber, and using the RF magnetron sputtering method to bombard the surface of the reflective metal layer such that the surface of the reflective metal layer and the reaction gas react to form a metal compound as the reflective layer. The present invention has both diffusion and reflection characters, and the manufacturing method of the reflective layer of this invention is simple in manufacturing process, and the reflectivity of the reflective layer is high, and cost is low.

### BACKGROUND OF THE INVENTION

1. Field of the Invention

The present invention relates to the field of liquid crystal display. More particularly, relates to a manufacturing method of a reflective layer for a reflective type liquid crystal display.

2. Description of Related Art

At present, in the flat panel display devices, thin film transistor liquid crystal display (Thin Film Transistor Liquid Crystal Display, TFT-LCD) has the characteristics of small size, low power consumption, low manufacturing cost and no radiation. In the current flat panel display market, it has dominant position. The thin film transistor liquid crystal display use a few volts as effective voltage to drive liquid crystal molecules to make them as light switches and change the light transmittance rate for showing information. The liquid crystal molecules cannot emit light themselves so that it requires an independent light source. Th reflective type liquid crystal display deposits a reflective layer for using the environment light as the independent light source. In addition, the reflective type liquid crystal display uses liquid crystal characteristics to eliminate the need of a backlight module to reduce power consumption. In the prior art, using the method for producing a high reflectivity thin film as the reflective layer of the reflective type liquid crystal display to improve the light reflectivity. However, there still exist complex processes, low reflectivity, and high cost problems.

Therefore, it requires providing a manufacturing method of reflective layer for a reflective type liquid crystal display.

### SUMMARY OF THE INVENTION

The main technical problem solving by the present invention is providing a manufacturing method of a reflective layer for the reflective type liquid crystal display, forming a high efficient diffusion and reflection layer.

To solve the above problem, a technical solution used in this invention is: providing a manufacturing method of a reflective layer for a reflective type liquid crystal display, comprising: providing a substrate comprising a reflective area and a non-reflective area; coating a photoresist to cover the non-reflective area of the substrate; placing the substrate in a sputtering chamber for depositing a reflective metal layer on the reflective area of the substrate; passing the reaction gas into the sputtering chamber, and using RF magnetron sputtering to bombard the surface of the reflective metal layer such that the surface of the reflective metal layer and the reaction gas react to produce metal compounds to form the reflective layer; wherein the reflective metal layer is a Al—Ni alloy layer, and the reaction gas is: a mixed gas of Ar and N₂ ora mixed gas of O₂ and N₂. In the mixed gas of Ar and N₂, the mixture ratio of Ar and N₂ ranges from 0.1 to 10. In the mixed gas of O₂ and N₂, the mixture ratio of O₂ and N₂ ranges from 0.1 to 10.

To solve the above problems, another technical solution used in this invention is: providing a manufacturing method of the reflective layer for a reflective type liquid crystal display, comprising: providing a substrate comprising a reflective area and a non-reflective area; coating photoresist to cover the non-reflective area; placing the substrate in the sputtering chamber for depositing a reflective metal layer on the reflective area of the substrate; passing the reaction gas into the sputtering chamber, and using the RF magnetron sputtering to bombard the surface of the reflective metal layer such that the surface of the reflective metal layer and the reaction gas react to produce metal compounds to form the reflective layer.

Wherein, the reflective metal layer is an Al—Ni alloy layer.

Wherein, the reaction gas is N₂ and the metal compound is AlN.

Wherein, the reaction gas is O₂ and the metal compound is Al₂O₃.

To solve the above problems, another technical solution used in this invention is: providing a manufacturing method of a reflective layer for a reflective type liquid crystal display, comprising: providing a substrate comprising a reflective area and a non-reflective area; coating photoresist to cover the non-reflective area of the substrate; placing the substrate in the sputtering chamber for depositing a electrode metal layer on the reflective area of the substrate; passing the reaction gas into the sputtering chamber, and depositing a metal for a reflective layer such that when the metal for the reflective layer is being depositing on the surface of the electrode metal layer, the metal react with reaction gas to produce metal compounds to form the reflective layer.

Wherein, the metal for the reflective layer is Al.

Wherein, the reaction gas is N₂ and the metal compound is AlN.

Wherein, the reaction gas is O₂ and the metal compound is Al₂O₃.

Wherein, the reaction gas is a mixed gas of Ar and N₂ or a mixed gas of O₂ and N₂. In the mixed gas of Ar and N₂, the mixture ratio of Ar and N₂ ranges from 0.1 to 10. In the mixed gas of O₂ and N₂, the mixture ratio of O₂ and N₂ ranges from 0.1 to 10.

The beneficial effects of the present invention are: comparing to the prior technology, the manufacturing method of the reflective layer for the reflection type liquid crystal display of the present invention use RF magnetron sputtering to bombard the surface of the reflective metal layer or to deposit the metal for the reflective layer in the chamber to form a uneven reflective layer having both diffusion and reflection characters. Besides, the manufacturing method of the reflective layer in this invention is simple in manufacturing process, and has high reflectivity and low cost characters.

### BRIEF DESCRIPTION OF THE DRAWINGS

In order to more clearly illustrate the technical solutions in the embodiments, the following will simply describe the figures in the embodiments. Obviously, the following descriptions of the figures are just some embodiments of the present invention. The person of ordinary skill who does not pay the creative work under the premise can derive other figures according to these figures. In the figures,

FIG. 1 is a flow chart of the manufacturing method of the reflective layer according to the first embodiment of this invention;

FIG. 2 is a cross-section view of the reflective layer of the substrate according to the first embodiment of this invention;

FIG. 3 is a cross-section view of non-reflective area in FIG. 2 covering photoresist;

FIG. 4 is a cross-section view of the reflective layer according to the first embodiment of this invention;

FIG. 5 is a flow chart of the manufacturing method of the reflective layer according to the second embodiment of this invention;

FIG. 6 is a cross-section view of the reflective layer according to the second embodiment of this invention.

### DETAILED DESCRIPTION OF THE PREFERRED EMBODIMENT

The present invention provides a manufacturing method of a reflective layer for a reflective type liquid crystal display. The manufacturing method can not only be applied to the reflective type liquid crystal display but also be applied to transflective type liquid crystal display. The following descriptions are the manufacturing method applied in the reflective type liquid crystal display as an example for detail descriptions of the technical solution of the present invention.

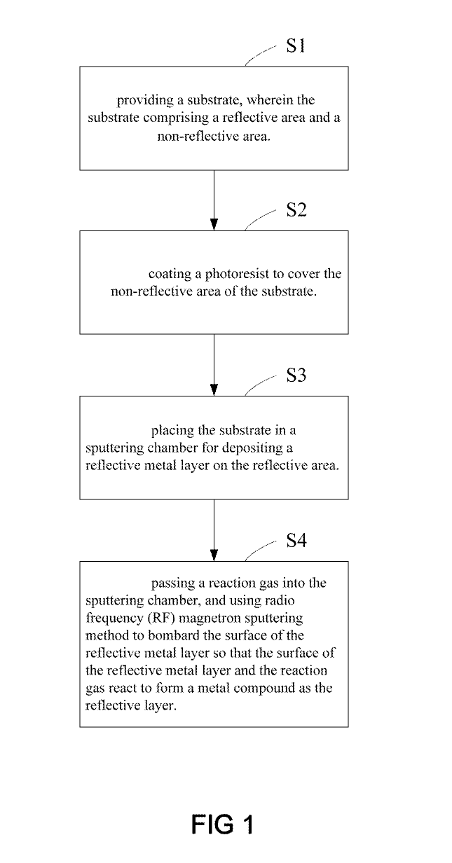

Please refer to FIG. 1, FIG. 1 is a flow chart of the manufacturing method of a reflective layer according to the first embodiment Of this invention. As shown in FIG. 1, the manufacturing method of the reflective layer includes the following steps:

Step S1: providing a substrate, wherein the substrate comprising a reflective area and a non-reflective area;

Step S2: coating a photoresist to cover the non-reflective area of the substrate;

Step S3: placing the substrate in the sputtering chamber for depositing a reflective metal layer on the reflective area;

Step S4: passing a reaction gas into the sputtering chamber, and using radio frequency (RF) magnetron sputtering method to bombard the surface of the reflective metal layer so that the surface of the reflective metal layer and the reaction gas react to form metal compound as the reflective layer.

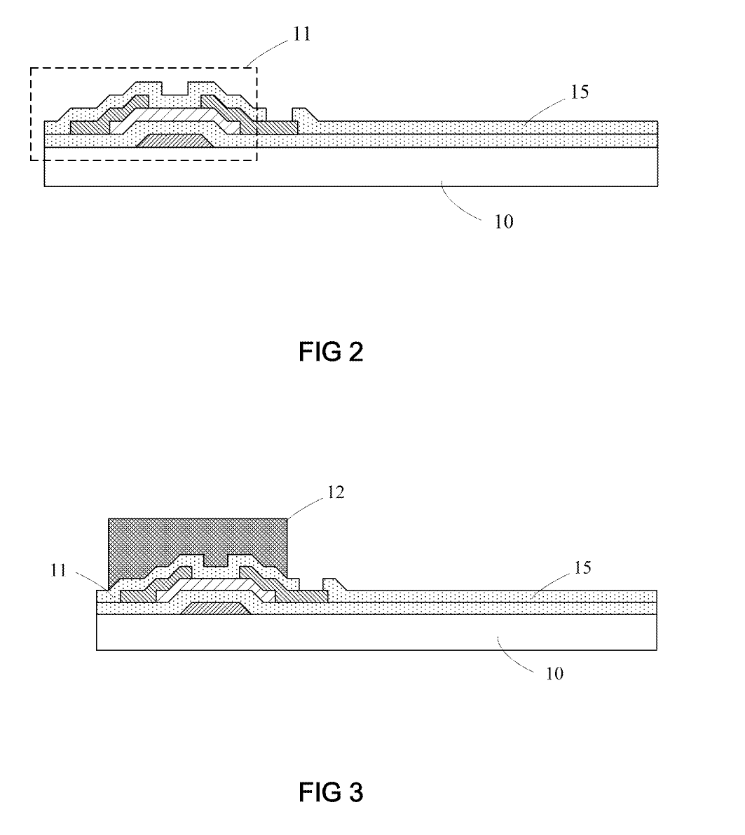

As shown in FIG. 2, the Step Si further includes: manufacturing a TFT (Thin Film Transistor) device 11 on the substrate 10, wherein the TFT device 11 is the non-reflective area, and disposing a SiNx layer 15 on the reflective area of the substrate 10. In this embodiment, the substrate 10 is preferably made of glass.

As shown in FIG. 3, in the Step S2, using the photoresist 12 to cover the TFT device 11 of the substrate 10. The thickness of the photoresist 12 is 2 μm˜8 μm.

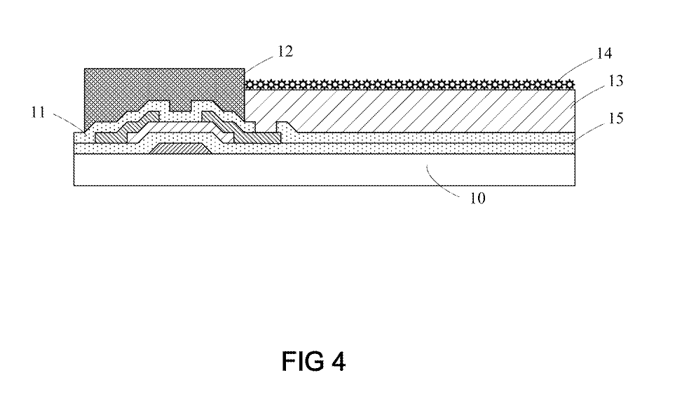

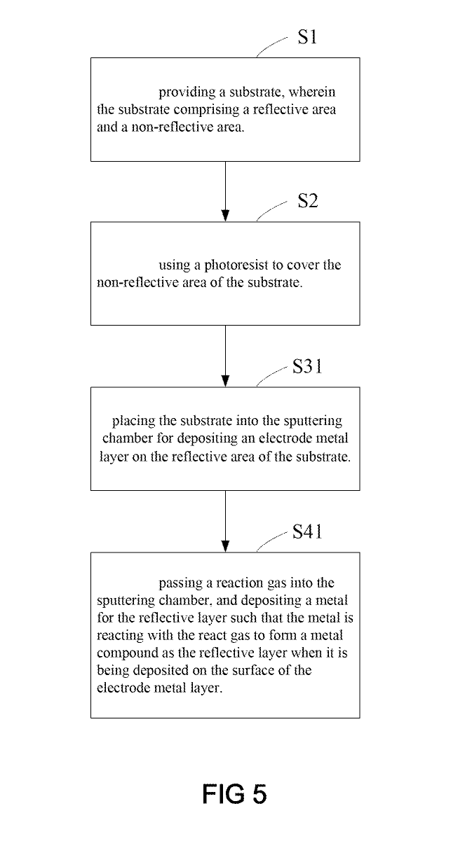

In the Step S3, the reflective metal layer 13 is deposited on the reflective area on the SiNx layer 15 as shown in FIG. 4, wherein, the reflective metal layer 13 is an Al—Ni alloy layer.

In the Step S4, when the reaction gas is N₂, using RF magnetron sputtering method to bombard the surface of the reflective metal layer 13 such that the surface of the reflective metal layer 13 react with the reaction gas N₂, and forming a high reflective metal compound, AlN, as the reflective layer 14. When the reaction gas is O₂, using RF magnetron sputtering method to bombard the surface of the reflective metal layer 13 such that the surface of the reflective metal layer 13 react with the reaction gas O₂, and forming a high reflectivity metal compound, Al₂O₃, as the reflective layer 14. In other embodiments, the person in this technical field can select a mixed gas as the reaction gas, such as a mixed gas of Ar and N₂ ora mixed gas of O₂ and N₂, wherein, in the mixed gas of Ar and N₂, the mixture ratio of Ar and N₂ ranges from 0.1 to 10, and in the mixed gas of O₂ and N₂, the mixture ratio of O₂ and N₂ ranges from 0.1 to 10.

Comparing to the manufacturing method of the reflective layer for the reflection type liquid crystal display in the prior art, the present invention use RF magnetron sputtering method to bombard the surface of the reflective metal layer 13 such that the surface of the reflective metal layer 13 react with the reaction gas to form the high reflectivity metal compound. Besides, after bombardment, the reflective metal layer 13 form the uneven reflective layer 14 having both diffusion and reflection characters.

Please refer to FIG. 5. FIG. 5 is a flow chart of the manufacturing method of the reflective layer according to the second embodiment of this invention. As shown in FIG. 5, the manufacturing method of the reflective layer includes the following steps:

According to the Step S1 and the Step S2 described from FIG. 1 to FIG. 3, using the photoresist 12 to cover the TFT device 11 on the substrate 10;

Step S31: Placing the substrate 10 into the sputtering chamber for depositing an electrode metal layer 16 on the reflective area of the substrate 10;

Step S41: Passing the reaction gas into the sputtering chamber, and depositing a metal for a reflective layer such that the metal is reacting with the react gas to form a metal compound when it is being deposited on the surface of the electrode metal layer 16.

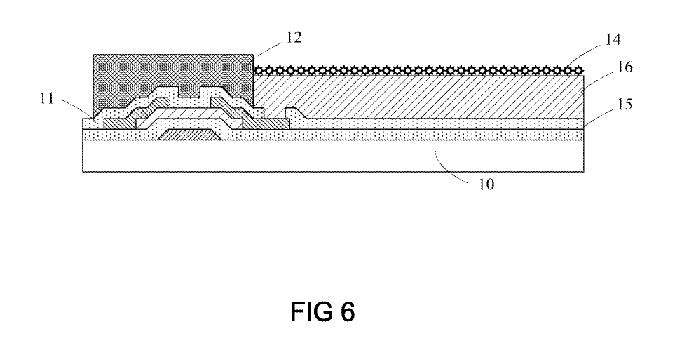

As shown in FIG. 6, in the Step S31, the electrode metal layer 16 is deposited on the SiNx layer 15 of the reflective area.

In the Step S41, the metal for the reflective layer is preferably made of Al. When the reaction gas is N₂, depositing the metal, Al, for the reflective layer on the surface of the electrode metal layer 16 such that the metal, Al, react with the reaction gas N₂, and forming a high reflective metal compound, AlN, as the reflective layer 14. When the reaction gas is O₂, depositing the metal, Al, for the reflective layer on the surface of the electrode metal layer 16 such that the metal, Al, react with the reaction gas O₂, and forming a high reflective metal compound, Al₂O₃, as the reflective layer 14. In other embodiments, the person in this technical field can select a mixed gas as the reaction gas, such as a mixed gas of Ar and N₂ or a mixed gas of O₂ and N₂, wherein, in the mixed gas of Ar and N2, the mixture ratio of Ar and N₂ ranges from 0.1 to 10, and in the mixed gas of O₂ and N₂, the mixture ratio of O₂ and N₂ ranges from 0.1 to 10.

Comparing to the manufacturing method of the reflective layer for the reflective type liquid crystal display in the prior art, the present invention depositing the metal, Al, for the reflective layer such that the metal, Al, react with the reaction gas to form a high reflectivity metal compound, and forming the uneven reflective layer 14 having both diffusion and reflection characters.

In summary, the manufacturing method of the reflective layer for the reflective type liquid crystal display of the present invention use RF magnetron sputtering method to bombard the surface of the reflective metal layer or deposit a metal for a reflective layer in the chamber to form the uneven reflective layer having both diffusion and reflection characters. The manufacturing method of the reflective layer of this invention is simple in manufacturing process, and the reflectivity of the reflective layer is high, and cost is low.

The above the embodiments of the present invention are not used to limit the claims of this invention. Any use of the content in the specification or in the figures of the present invention which produces the equivalent structures or an equivalent process, or directly or indirectly used in other related technical fields is still covered by the claims in the present invention.

What is claimed is:

1. A manufacturing method of a reflective layer for a reflective type liquid crystal display, comprising:
providing a substrate, wherein the substrate comprising a reflective area and a non-reflective area;
coating a photoresist to cover the non-reflective area of the substrate;
placing the substrate in a sputtering chamber for depositing a reflective metal layer on the reflective area and
passing a reaction gas into the sputtering chamber, and using radio frequency (RF) magnetron sputtering method to bombard the surface of the reflective metal layer so that the surface of the reflective metal layer and the reaction gas react to form a metal compound as the reflective layer,
wherein the reflective metal layer 13 is an Al—Ni alloy layer, and the reaction gas is a mixed gas of Ar and N₂ or a mixed gas of O₂ and N₂, wherein, in the mixed gas of Ar and N₂, the mixture ratio of Ar and N₂ ranges from 0.1 to 10, and in the mixed gas of O₂ and N₂, the mixture ratio of O₂ and N₂ ranges from 0.1 to 10.

2. A manufacturing method of a reflective layer for the reflective type liquid crystal display, comprising:
providing a substrate, wherein the substrate comprising a reflective area and a non-reflective area;
coating a photoresist to cover the non-reflective area of the substrate;
placing the substrate in a sputtering chamber for depositing a reflective metal layer on the reflective area; and
passing a reaction gas into the sputtering chamber, and using radio frequency (RF) magnetron sputtering method to bombard the surface of the reflective metal layer so that the surface of the reflective metal layer and the reaction gas react to form a metal compound as the reflective layer.

3. The manufacturing method of claim 2, wherein the reflective metal layer is an Al—Ni alloy layer.

4. The manufacturing method of claim 3, wherein the reaction gas is N₂, and the metal compound is AlN.

5. The manufacturing method of claim 3, wherein the reaction gas is O₂, and the metal compound is Al₂O₃.

6. A manufacturing method of a reflective layer for a reflective type liquid crystal display, comprising:
providing a substrate, wherein the substrate comprising a reflective area and a non-reflective area;
using a photoresist to cover the non-reflective area of the substrate;
placing the substrate into the sputtering chamber for depositing an electrode metal layer on the reflective area of the substrate; and
passing a reaction gas into the sputtering chamber, and depositing a metal for the reflective layer such that the metal is reacting with the react gas to form a metal compound as the reflective layer when it is being deposited on the surface of the electrode metal layer.

7. The manufacturing method of claim 6, wherein the metal for the reflective layer is Al.

8. The manufacturing method of claim 7, wherein the reaction gas is N₂, and the metal compound is AlN.

9. The manufacturing method of claim 7, wherein the reaction gas is O₂, and the metal compound is Al₂O₃.

10. The manufacturing method of claim 7, wherein the reaction gas is a mixed gas of Ar and N₂ or a mixed gas of O₂ and N₂, wherein, in the mixed gas of Ar and N₂, the mixture ratio of Ar and N₂ ranges from 0.1 to 10, and in the mixed gas of O₂ and N₂, the mixture ratio of O₂ and N₂ ranges from 0.1 to 10.
